(19) United States
(12) Patent Application Publication
(10) Pub. No.: US 2026/0349052 A1
(43) Pub. Date: Nov. 5, 2026

(54) CORRECTION METHOD FOR CORRECTING THE OUTPUT VOLTAGE OF A MAGNETIC SENSOR

(71) Applicant: Allegro MicroSystems, LLC, Manchester, NH (US)

(72) Inventors: Santiago Serrano-Guisan, San Jose, CA (US); Hakan Ates Gurcan, Los Gatos, CA (US); Ali Alaoui, Polienas (FR); Anuraag Mohan, Fremont, CA (US); Ehsan Aerabi, La Tronche (FR)

(73) Assignee: Allegro MicroSystems, LLC, Manchester, NH (US)

(21) Appl. No.: 18/997,643

(22) PCT Filed: Jul. 20, 2023
(86) PCT No.: PCT/IB2023/057421

§ 371 Date: Jan. 22, 2025

(30) Foreign Application Priority Data
Jul. 22, 2022 (EP) 22315164.8

(51) Int. Cl. G01R 33/00; G01R 33/09

(52) U.S. Cl. CPC G01R 33/0029; G01R 33/098

(57) ABSTRACT

The present disclosure concerns a correction method for correcting an output voltage signal provided by a magnetic sensor, comprising: providing a sensor, comprising at least a magnetoresistive element, inputting the sensor by a bias voltage in the presence of the external magnetic field vector such that the sensor generates the output voltage signal; and determining a corrected output voltage signal from the output voltage signal, where the corrected output voltage signal has a linearity error smaller than the linearity error of the output voltage signal. The corrected output voltage signal is determined by applying a hyperbolic function or an inverse hyperbolic function or a combination of a hyperbolic function or an inverse hyperbolic function, to a signal proportional to the output voltage signal, or to an additional voltage signal being added or subtracted to the output voltage signal.

### TECHNICAL DOMAIN

The present disclosure concerns a correction method for correcting an output voltage signal provided by a magnetic sensor in the presence of an external magnetic field. The present disclosure further concerns an integrated circuit (IC) configured to perform the method.

### RELATED ART

Linear magnetic sensors have many consumer, industrial and automotive applications. Current sensing, positioning, proximity detection, biometric sensing are some examples. Sensor technologies using Magnetic Tunnel Junctions (MTJs) based on Tunnel Magneto-Resistance (TMR) effect excel among rival technologies based on Anisotropic Magneto-Resistance (AMR) effect, Giant Magneto-Resistance (GMR) effect and Hall effect, thanks to their higher sensitivity and signal-to-noise ratio (SNR), lower temperature dependence, better long-term stability and generally smaller die size.

FIG. 1 shows an exemplary magnetic sensor 2 comprising four magnetic sensing elements 20 arranged in a full-bridge circuit, such as a Wheatstone bridge circuit. The magnetic sensing element 20 can comprise a magnetoresistive element, such as a MTJ.

Commonly, a magnetic sensor provides a differential output voltage signal Vₒᵤₜ(Vₒᵤₜ=Vₒᵤₜ₊−Vₒᵤₜ₋) that is roughly proportional to external applied magnetic field. However, the larger the magnetic field is, the larger is the deviation of Vₒᵤₜ from a perfect linear response.

The linearity of such magnetic sensor can generally be improved by the development of novel magnetic stacks enabling larger working magnetic field ranges. However, the improvement in linearity usually comes at the expense of a reduction of sensor sensitivity.

Some approaches were previously proposed to improve the linearity of such magnetic sensor without reduction of sensitivity. Such previous schemes were based either on piece-wise linear correction or by continuous compensation of next high order terms of the output voltage signal Vₒᵤₜ. Piece-wise linear correction can comprise segmentation of the overall output voltage signal Vₒᵤₜ response at different magnetic field ranges while continuous compensation of non-linearity relies on continuous addition of an extra voltage to the output voltage signal Vₒᵤₜ.

A typical response of a magnetic sensor inputted by a bias voltage V_{dd} and under an external magnetic field H can be approximated by equation 1:

$${V}_{out} = {v}_{s} ( H ) \cdot {V}_{dd} , \qquad Eq . 1$$

$$with$$

$${v}_{s} ( H ) = {a}_{0} + {a}_{1} \cdot H + {\sum }_{j = 1}^{N} {( - 1 )}^{j} \cdot {a}_{2 j + 1} \cdot {H}^{2 j + 1} , \qquad Eq . 2$$

where vₛ expresses the intrinsic dependence of the magnetic sensor when submitted to an external magnetic field (i.e., the normalized output voltage of the sensor), α₀ is the sensor offset, α₁ is a linear coefficient (or Sensitivity) and α₂ⱼ₊₁ are the high order components, respectively. Usually, α₁»α₂ⱼ₊₁, being each high order coefficient much larger than the next one. This implies that the larger is the working magnetic field range of the sensor the larger will be the impact of high order components on sensor's response, i.e., the output voltage signal Vₒᵤₜ.

FIG. 2 shows the linearity error derived from a magnetic sensor for different magnetic field ranges. Black dots show the linearity error derived by considering that the output voltage signal Vₒᵤₜ varies linearly with the external magnetic field H, Vₒᵤₜ~c₀+c₁·H, (Linear Fit). Open dots show the linearity error derived by considering that the output voltage signal Vₒᵤₜ is approximated to equation 3:

Vₒᵤₜ~[α₀+α₁·H−α₃·H³]·V_{dd} Eq. 3.

When the output voltage signal Vₒᵤₜ is fitted to a linear function (Lin Fit) linearity error increases rapidly with the considered magnetic field range (see dashed lines in FIG. 1), reaching values >1% for magnetic field ranges >40 mT. Such rapid increase of linearity error, due to the presence of additional high order components on the output voltage signal Vₒᵤₜ, limits the working magnetic field range of such sensors. The ratio between the third order coefficient and the linear coefficient (α₃/α₁) will therefore determine the linearity error of the sensor at a fixed magnetic field range or the working field range to obtain a linearity error below a certain value (see FIGS. 3a and b). In particular, FIG. 3a shows simulation of linearity error vs α₃/α₁ ratio for a magnetic field range of 100 mT, and FIG. 3b shows the maximum magnetic field range in order to have a linearity error <0.5% vs α₃/α₁ ratio.

Although commercial linear magnetic sensors usually work up to 40 mT, there are several applications where either high accuracy linear response might be required (<0.1%), such as in precise positioning for surgical or aerospace applications, or larger magnetic fields (up to 100 mT) might be involved.

In order to develop a highly-linear magnetic sensor, two different strategies can be considered including developing a different magnetic stack configuration, or developing correction strategies to reduce linearity error of the output voltage signal Vₒᵤₜ. Each strategy has its advantages and disadvantages as summarized in Table 1.

A previous work by the present applicant (International patent application PCT/IB2021/060743) has shown that some linearization correction methods can be implemented on linear magnetic sensors enabling a substantial improvement of linearity error with no loss in sensitivity, such that larger magnetic field ranges can be achieved. The methods rely on the compensation of high order component of the output voltage signal Vₒᵤₜ.

TABLE 1
Comparison of two principal non-linearity correction approaches

| | advantages | disadvantages |
|---|---|---|
| Magnetic | increase of working | Reduction of sensitivity |
| stack | magnetic field range | |
| devel- | simple architecture | |
| opment | low noise | |
| | low power consumption | |
| | fast response | |
| | no calibration required | |
| ASIC | increase of working | increase in power consumption |
| devel- | magnetic field range | impact on speed |
| opment | no reduction in sensitivity | potential increase of noise |
| | large improvement on | potential calibration required |
| | linearity | increase of cost/unit |
| | potentiality to be | additional architecture |
| | implemented in all linear | |
| | magnetic sensors | |

### SUMMARY

The present disclosure concerns a correction method for correcting an output voltage signal provided by a magnetic sensor, comprising:
providing a magnetic sensor, comprising at least a magnetic element, and generates the output voltage signal when inputted by a bias voltage and in the presence of an external magnetic field vector;
inputting the magnetic sensor by the bias voltage in the presence of the external magnetic field vector such that the magnetic sensor generates the output voltage signal; and
determining a corrected output voltage signal from the output voltage signal of the magnetic sensor, wherein the corrected output voltage signal has a linearity error smaller than the linearity error of the output voltage signal of the magnetic sensor.

Determining a corrected output voltage signal comprises applying a hyperbolic function or an inverse hyperbolic function or a combination of a hyperbolic function or an inverse hyperbolic function, to a signal proportional to the output voltage signal.

Alternatively, determining a corrected output voltage signal comprises adding or subtracting an additional voltage signal to the output voltage signal, the additional voltage signal being obtained by applying a hyperbolic function or an inverse hyperbolic function or a combination of both to a signal proportional to the output voltage signal.

The present disclosure further concerns an integrated circuit (IC) comprising a processor configured to perform the steps of the method.

The magnetic sensor can comprise a MTJ-based magnetic sensor, i.e., a magnetic sensor based on technologies using magnetic tunnel junctions (MTJs) based on tunnel magneto-resistance (TMR) effect. However, the magnetic sensor can comprise other types of magnetic sensors, such as a GMR-based magnetic sensor, an AMR-based magnetic sensor, a Hall effect-based magnetic sensor, etc. The magnetic sensor can be corrected by the correction method disclosed herein.

The correction method disclosed herein provides higher efficiency against higher order components of the output voltage signal, enabling to correct larger non-linearity errors, allowing the use of the magnetic sensor for larger magnetic field ranges. In other words, non-linear magnetic sensors with high initial sensitivity can be linearized while keeping the same high sensitivity values.

The corrected output voltage signal is relatively insensitive to sample-to-sample, temperature and operating voltage variations. The correction method has increased robustness against device-to-device, operating temperature and voltage variations and allows for improved linearity error correction, without degradation in sensitivity. The correction method can be performed by applying the same parameter set for all devices on a wafer, avoiding time consuming individual calibration procedures for each sensor device that might impact manufacturing cost and reliability performance.

Furthermore, the correction method presented is suitable for real time correction of non-linearity by analog means, thus allow high bandwidth operation. The method can also be applied to linearize the sinusoidal response of 2D magnetic sensors, improving the working angular range of such sensors for auto-focus (AF) applications.

### SHORT DESCRIPTION OF THE DRAWINGS

Exemplar embodiments of the invention are disclosed in the description and illustrated by the drawings in which:

FIG. 1 shows an exemplary magnetic sensor;

FIG. 2 shows the linearity error derived from an MTJ based linear sensor for different magnetic field ranges;

FIGS. 3a and 3b show simulation of linearity error vₛ first order coefficient/third order coefficient ratio for a magnetic field range of 100 mT (FIG. 3a) and maximum magnetic field range in order to have a linearity error <0.5% (FIG. 3b);

FIG. 4 reports the performance of the three hyperbolic correction schemes involving a Sin h function and Arc tan h function (FIG. 4a and FIG. 4b), and a Tan h function (FIGS. 4c and 4b);

FIG. 5 shows linearity error dependence on the correction parameter for a correction scheme involving a Sin h function (FIG. 5a), for a correction scheme involving a Arc tan h function (FIG. 5b) and for a correction scheme involving a Tan h function(FIG. 5c);

FIG. 6 reports the variations of the correction parameters around their optimal values for the correction scheme involving a Sin h function (FIG. 6a), for the correction scheme involving an Arc tan h function (FIG. 6b), and for the correction scheme involving a Tan h function (FIG. 6c);

FIG. 7 shows the magnetic field dependence of the output voltage signal (FIG. 7a) and the magnetic field dependence of the linearity error (FIG. 7b) for the output voltage of the magnetic sensor (Vₒᵤₜ) as well as for the corrected output voltage signal for a correction scheme involving a Sin h function, a correction scheme involving a Arc tan h function and a correction scheme involving a Tan h function, FIG. 7c show the linearity error as a function of the external magnetic field range for a correction scheme involving a Sin h function, for a correction scheme involving a Arc tan h function and for a correction scheme involving a Tan h function in comparison to Vₒᵤₜ.

FIG. 8 shows the performance of a magnetic sensor, here a 2D angular sensor in a dual full-bridge configuration for a correction scheme involving a Sin h function, for a correction scheme involving a Arc tan h function and for a correction scheme involving a Tan h function, reporting the corrected output voltage signal as a function of the external magnetic field (FIG. 8a), the linearity error of the corrected output voltage signal as a function of the external magnetic field (FIG. 8b), and the linearity error as a function of the external magnetic field range (FIG. 8c);

FIG. 9 shows the dependence of the output voltage signal (FIG. 9a) and linearity error (FIG. 9b) of a magnetic sensor as a function of the magnetic field orientation in comparison to the dependence of a corrected output voltage and its linearity error as a function of the magnetic field orientation, according to three different type of correction schemes involving different hyperbolic functions

FIG. 10 shows the dependence on temperature of the output voltage signal (FIG. 10a) and linearity error (FIG. 10b) of a magnetic sensor as a function of temperature, according to another embodiment;

FIG. 11 reports the performance of the three different correction schemes for a magnetic sensor in a dual full-bridge configuration for the temperatures −40 °C, 30 °C, 85 °C and 125 °C, where the corrected output voltage signal (FIGS. 11a, c and e) and linearity error (FIGS. 10b, d and f) are reported for a correction scheme involving a Sin h function (FIGS. 11a, b), for a correction scheme involving a Arc tan h function (FIGS. 10b, d), and for a correction scheme involving a Tan h function (FIGS. 11e, f); and

FIG. 12 reports the sensitivity (FIG. 12a) and the linearity error (FIG. 12b) as a function of temperature of a magnetic sensor in a dual full-bridge configuration for a correction scheme involving a Sin h function, for a correction scheme involving a Arc tan h function, and for a correction scheme involving a Tan h function.

### EXAMPLES OF EMBODIMENTS

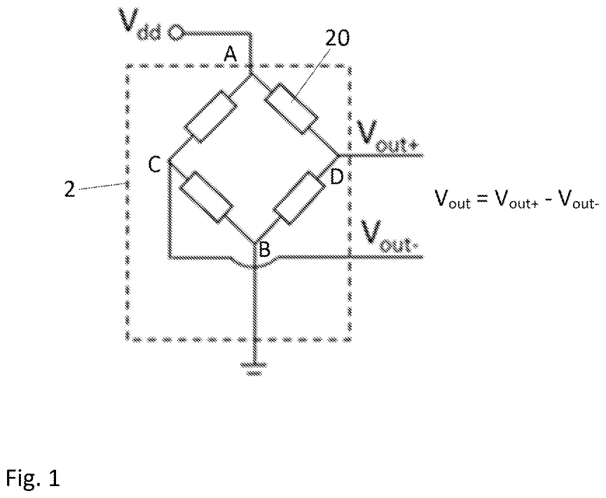

A typical voltage response (output voltage signal Vₒᵤₜ) of a magnetic sensor (such as the one shown in FIG. 1) inputted by a bias voltage V_{dd} and under an external magnetic field H can be further described by equation 4:

Vₒᵤₜ=[α₀+α₁·H+Vₕₒ]·V_{dd} Eq. 4,

where Vₒᵤₜ is an output voltage signal of the magnetic sensor, α₀ is a sensor offset, α₁ is a linear coefficient (or Sensitivity), and Vₕₒ is a high order component voltage, expressing the contribution to the output voltage signal Vₒᵤₜ from all non-linear components. The high order component voltage Vₕₒ can be described by equation 5:

$${V}_{ho} = {\sum }_{j = 1}^{N} {( - 1 )}^{j} \cdot {a}_{2 j + 1} \cdot {H}^{2 j + 1} , \qquad Eq . 5$$

where α₂ⱼ₊₁ are a high order coefficients.

Alternatively, the output voltage signal Vₒᵤₜ can be approximated by equation 6:

Vₒᵤₜ=[α₀+α₁·θ+Vₕₒ]·V_{dd} Eq. 6,

where θ is the orientation of the external magnetic field H with respect to a certain predefined axis in a coordinate system. The high order component voltage Vₕₒ can be described by equation 7:

$${V}_{ho} = {\sum }_{j = 1}^{N} {( - 1 )}^{j} \cdot {a}_{2 j + 1} \cdot {θ}^{2 j + 1} , \qquad Eq . 7$$

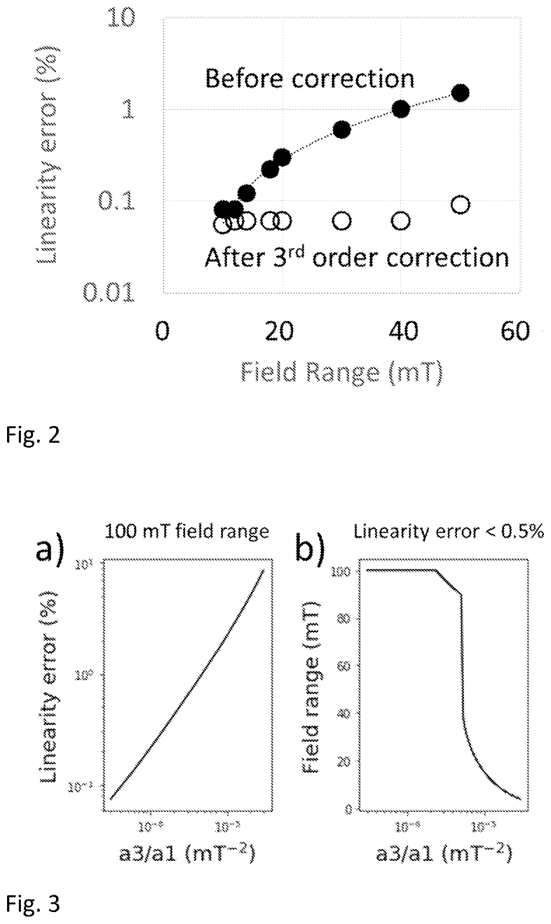

The deviation of the output voltage signal Vₒᵤₜ from a perfect linear response (so called “linearity error” or “non-linearity”) is determined by the amplitude of the high order component voltage Vₕₒ, which rapidly increases with the amplitude of the applied external magnetic field H which, in turn, causes an increase in linearity error (see FIG. 2). A similar behavior occurs when increasing the orientation θ of the external magnetic field with respect to a certain predefined axis in a coordinate system.

It will be understood that the magnetic sensor 2 can have a different configuration that the one illustrated in FIG. 1. For example, the magnetic sensor 2 can comprise any other number of magnetic sensing elements 20, arranged in a bridge circuit or otherwise. The magnetic sensing element 20 can comprises a magnetoresistive element, such as a MTJ. As discussed above, the magnetic sensing element 20 can comprise other types of magnetic sensing element, such as based on GMR, AMR, Hall effect, etc.

In an embodiment, a method for correcting the output voltage signal Vₒᵤₜ of at least a magnetic sensor comprises determining a corrected output voltage signal V_{corr} by applying a hyperbolic function or an inverse hyperbolic function or a combination of a hyperbolic function or an inverse hyperbolic function, to a signal proportional to the output voltage Vₒᵤₜ.

In one aspect, a first possible error correction scheme is an Arc tan h scheme, where the magnetic sensor is configured to output a corrected output voltage signal V_{corr} that is determined by equation 8:

V_{corr}~A·arc tan h(b·Vₒᵤₜ) Eq. 8a,

where A and b are correction parameters that are independent of the external magnetic field vector H. Note, however that b is the main parameter for such a correction scheme as it determines the linear response of the corrected output voltage V_{corr} while factor A·b determines the desired amplitude of the corrected output voltage V_{corr}. A particular example of this correction scheme is determined by Eq. 8b:

V_{corr}~γ·arc tan h(Vₒᵤₜ/γ) Eq. 8b,

with A=γ and b=1/γ and γ are independent of the magnetic field vector H.

A second error correction scheme is a Sin h scheme, where the magnetic sensor is configured to output a corrected output voltage signal V_{corr} that is determined described by equation 9a:

V_{corr}~A·sinh(b·Vₒᵤₜ) Eq. 9a,

where A and b are correction parameters that are independent of the external magnetic field vector H. Note, however that b is the main parameter for such a correction scheme as it determines the linear response of the corrected output voltage V_{corr} while factor A·b determines the desired amplitude of the corrected output voltage V_{corr}. A particular example of this correction scheme is determined by Eq. 9b:

V_{corr}~α·sinh(Vₒᵤₜ/α) Eq. 9b,

with A=α and b=1/α and α are independent of the magnetic field vector H.

A third error correction scheme is a Tan h scheme, where the magnetic sensor is configured to output a corrected output voltage signal V_{corr} that is determined by equation 10a:

V_{corr}~C·Vₒᵤₜ−A·tan h(b·Vₒᵤₜ) Eq. 10a

Where A, C and b correction parameters that are independent of the external magnetic field vector H. Note, however that for such a correction scheme all three parameters A, C and b determine both the linear response of the corrected output voltage V_{corr} and the amplitude of the corrected output voltage V_{corr}. A particular example of this correction scheme is determined by Eq. 10b:

V_{corr}~2·Vₒᵤₜ−β·tan h(Vₒᵤₜ/β) Eq. 10b,

with A=β, b=1/β and C=2 and β are independent of the magnetic field vector H.

Note that in this embodiment, the corrected output voltage V_{corr} (in equations 10a and 10b) is determined by adding or subtracting an additional voltage signal V_{add} to the output voltage signal Vₒᵤₜ. The additional voltage signal V_{add} is obtained by applying a hyperbolic function or an inverse hyperbolic function or a combination of both to a signal proportional to the output voltage signal Vₒᵤₜ. In equations 10a and 10b, the second term corresponds to an additional voltage V_{add}, namely, V_{add}=A·tan h(b·Vₒᵤₜ) and V_{add}=β·tan h(Vₒᵤₜ/β), respectively.

For such particular correction schemes (described by Eq. 8b, 9b and 10b), fine tuning correction parameters γ, α and β allows for obtaining a corrected output voltage V_{corr}~(α₀+α₁·H)·V_{dd}.

Other hyperbolic functions can also be used in the error correction scheme. For example, another error correction scheme can comprise a Cosh scheme, where the magnetic sensor is configured to output a corrected output voltage signal V_{corr} that is determined by equation 11:

V_{corr}=A·cosh(b·Vₒᵤₜ) Eq. 11,

where A and b are correction parameters independent of the magnetic field vector H.

Yet another error correction scheme can comprise a combination of a hyperbolic function and an inverse hyperbolic function scheme, where the magnetic sensor is configured to output a corrected output voltage signal V_{corr} that is determined by equation 12:

V_{corr}=C·tan h(A·arc tan h(b·Vₒᵤₜ)) Eq. 12,

where A, C and b are correction parameters independent of the magnetic field vector H.

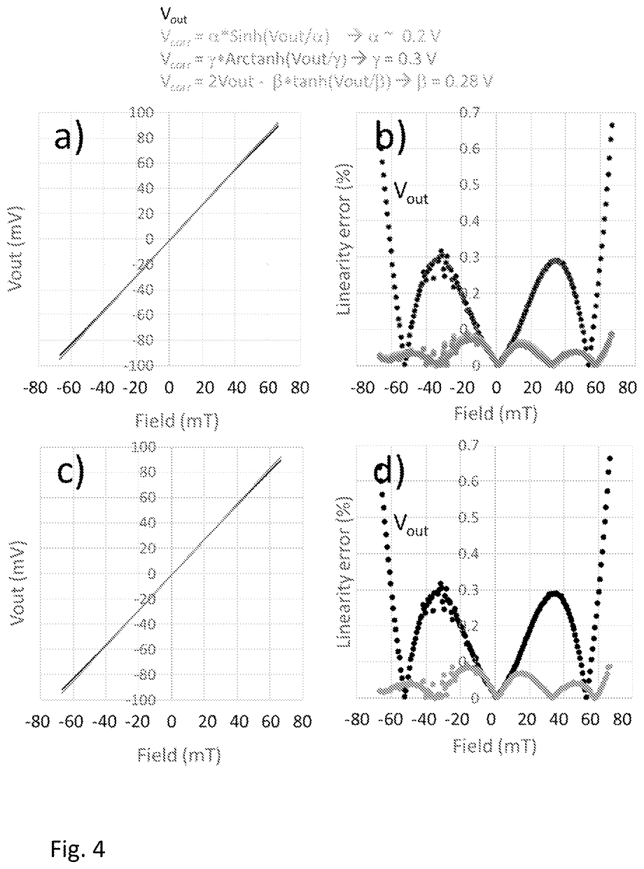

FIG. 4 reports the performance of the three hyperbolic correction schemes “Arc tan h”, “Sin h” and “Tan h”, on improving linearity error of the magnetic sensor when the bias voltage V_{dd}=1V. More particularly, FIG. 4a shows the corrected output voltage signal V_{corr} following the “Arc tan h” scheme (Eq. 8b) and “Sin h” scheme (Eq. 9b) as a function of the external magnetic field H. FIG. 4b reports the linearity error of the corrected output voltage signal V_{corr} following the “Arc tan h” scheme (Eq. 8b) and the “Sin h” scheme (Eq. 9b) as a function of the external magnetic field H. FIG. 4c shows the corrected output voltage signal V_{corr} following the “Tan h” scheme (Eq. 10b) as a function of the external magnetic field H, and FIG. 4d reports the linearity error of the corrected output voltage signal V_{corr} following the “Tan h” scheme (Eq. 10b) as a function of the external magnetic field H. In FIGS. 4a to 4d, the corrected output voltage signal V_{corr} and the linearity error are compared with the output voltage signal Vₒᵤₜ and the linearity error of output voltage signal Vₒᵤₜ.

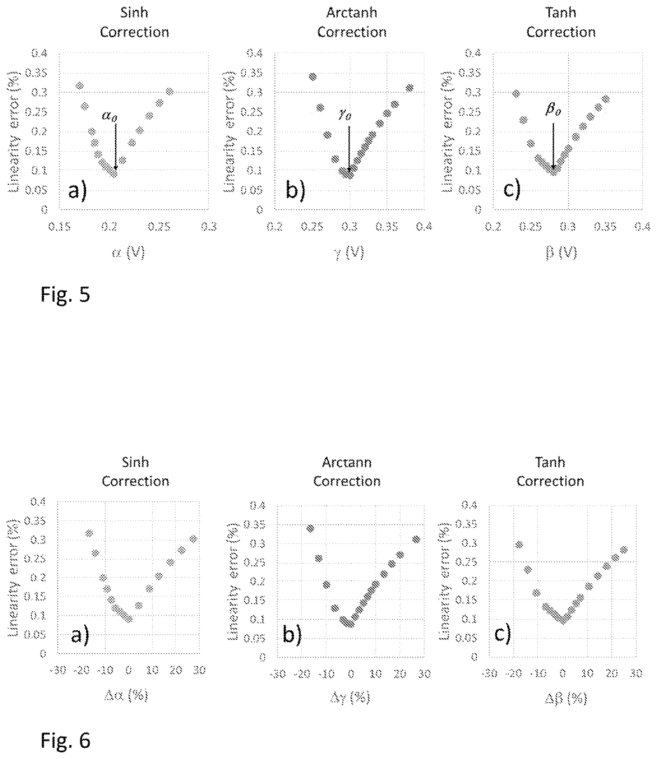

The correction schemes of equations 8b, 9b and 10b show high robustness against correction parameter variability. For example, FIG. 5 shows linearity error dependence on the correction parameter γ, α and β for each correction scheme for the magnetic sensor when submitted to an external magnetic field up to 67 mT and a bias voltage V_{dd} of 1V. In particular, FIG. 5a reports linearity error dependence for the “Sin h” scheme (Eq. 8b), FIG. 5b reports linearity error dependence for the “Arc tan h” scheme (Eq. 9b), and FIG. 5c reports linearity error dependence for the “Tan h” scheme (Eq. 10b). Note that the minimum linearity error is obtained for optimal values of the correction parameters, denoted α₀, γ₀ and β₀ in FIG. 5.

FIG. 6 reports the variations Δα, Δγ and Δβ of the correction parameters γ, α and β, respectively, around their optimal values α₀, γ₀ and β₀ for the “Sin h” scheme described by Eq. 9b (FIG. 6a), the “Arc tan h” scheme describe by Eq. 8b (FIG. 6b), and the “Tan h” scheme described by Eq. 10b (FIG. 6c). FIG. 6 shows that for a variation of correction parameters of about ±10% around its optimal values α₀, γ₀ and β₀, linearity errors smaller than about 0.2% are obtained.

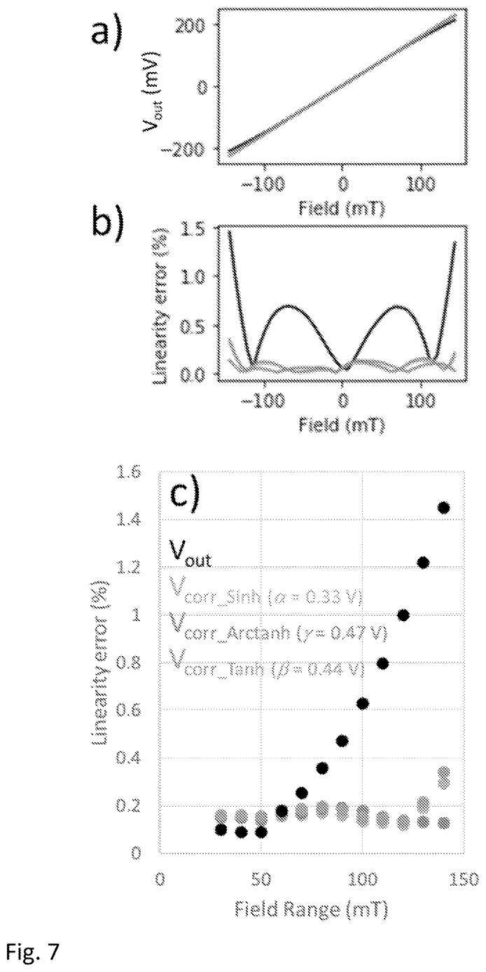

FIG. 7 shows the corrected output voltage signal V_{corr} and the linearity error of the corrected output voltage signal V_{corr} for a magnetic sensor under external magnetic fields H up to 140 mT. In particular, FIG. 7a reports the corrected output voltage signal V_{corr} following the “Arc tan h” scheme (Eq. 8b), the “Sin h” scheme (Eq. 9b) and “Tan h” scheme (Eq. 10b) as a function of the external magnetic field H. FIG. 7b reports the linearity error of the corrected output voltage signal V_{corr} for the “Arc tan h”, “Sin h”, and “Tan h” correction scheme (Equations 8b, 9b and 10b, respectively) as a function of the external magnetic field H. FIG. 7c reports the linearity error as a function of the external magnetic field range for the “Arc tan h”, “Sin h”, and “Tan h” correction scheme (Equations 8b, 9b and 10b, respectively). In FIGS. 7a to 7c, the correction parameters α=0.33 V, γ=0.47 V and β=0.44 V were used. The corrected output voltage signal V_{corr} and its linearity error are compared with the output voltage signal Vₒᵤₜ the linearity error of output voltage signal Vₒᵤₜ.

Depending on the case, the Arc tan h, Sin h, and Tan h correction schemes provide similar corrected output voltage signals V_{corr}. However, in some situations the Arc tan h correction scheme can perform better than Sin h and Tan h correction schemes.

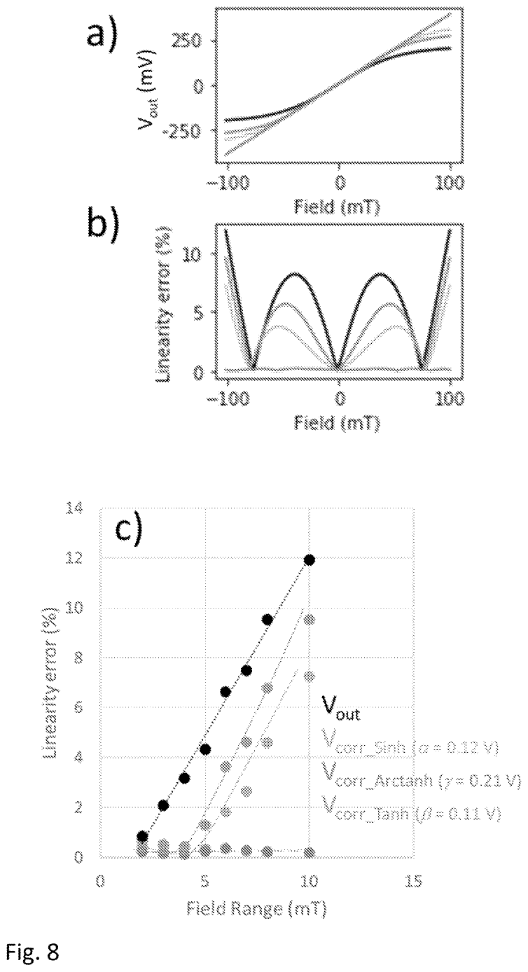

FIG. 8 shows the performance of a magnetic sensor, here a 2D angular sensor, for the Arc tan h, Sin h, and Tan h correction schemes determined by Equations 8b, 9b and 10b as described as “Arc tan h”, “Sin h” & “Tan h” correction schemes, respectively, and for external magnetic fields up to 10 mT. In particular, FIG. 8a reports the corrected output voltage signal V_{corr} as a function of the external magnetic field H, FIG. 8b reports the linearity error of the corrected output voltage signal V_{corr} as a function of the external magnetic field H, and FIG. 8c reports the linearity error as a function of the external magnetic field range. For this, the correction parameters γ=0.21 V, α=0.12 V and β=0.11 V were used for correction schemes described by Eq. 8b, Eq. 9b & Eq. 10b respectively.

For an external magnetic field range up to 10 mT, the output voltage signal Vₒᵤₜ shows a large non-linear response as shown by black curve in FIG. 8a with a high linearity error >10%. Indeed, such magnetic sensor only shows good linear performance (Linearity error <1%) at magnetic fields smaller than 1 mT (see FIG. 8c).

However, using “Tan h” or “Sin h” correction schemes (Eq. 10b or Eq. 9b respectively) allows for obtaining corrections linearity error smaller than 1% at magnetic field ranges up to 5 mT. When using the “Arc tan h” correction scheme (Eq. 8b) a linearity error <0.3% is obtained for magnetic field ranges up to 10 mT.

This shows the advantage of using these correction schemes (described by Eqs. 8b, 9b & 10b) for obtaining a magnetic sensor having a very high Sensitivity (up to 40 mV/V/mT) and very low linearity error (<0.3%) for fields up to 10 mT.

In one aspect, the output voltage Vₒᵤₜ is approximated by equation 4 or by equation 6.

Previously described correction schemes are specific embodiments for linearity correction of magnetic sensors with output voltages described, up to a 3^{rd} order approximation, by:

Vₒᵤₜ~[α₀+α₁·H−α₃·H³]·V_{dd} Eq. 14a,

or by:

Vₒᵤₜ~[α₀+α₁·θ−α₃·θ³]·V_{dd} Eq. 14b.

However, yet another error correction schemes based on hyperbolic functions and inverse hyperbolic functions could be used for different dependence of the Vₒᵤₜ with respect to the magnetic field vector H.

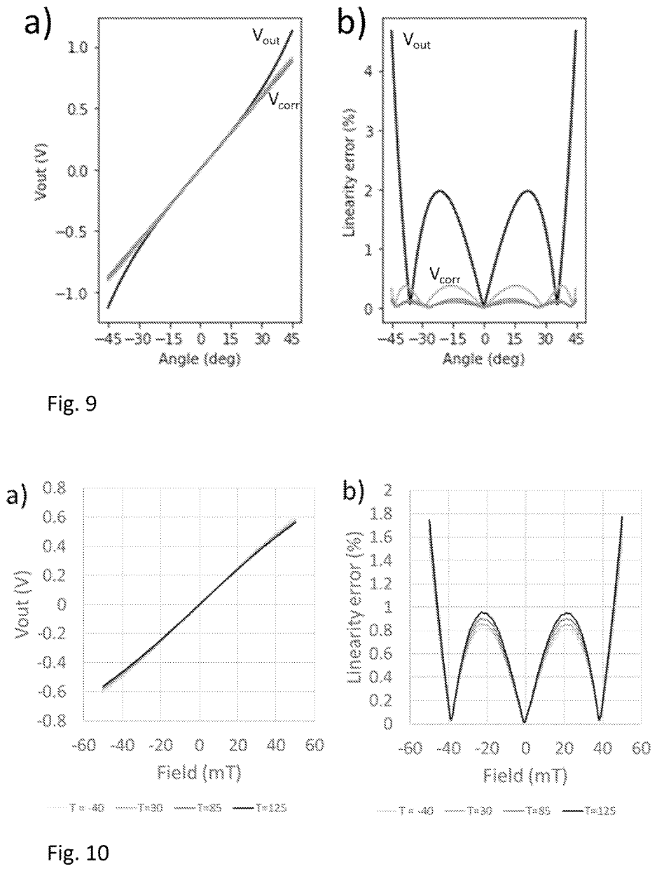

FIG. 9 shows the dependence of the output voltage signal (FIG. 9a) and linearity error (FIG. 9b) of a magnetic sensor as a function of the magnetic field orientation θ with an output voltage described by:

Vₒᵤₜ~[α₀+α₁·θ+α₃·θ³]·V_{dd} Eq. 15

For this situation different schemes than previously proposed (Eq. 8, 9 and 10) need to be considered.

At such conditions, a corrected output voltage signal V_{corr} based on a Tan h function can be obtained by equation 16a:

V_{corr}~A·tan h(b·Vₒᵤₜ) Eq. 16a,

where A and b are correction parameters that are independent of the external magnetic field vector H. Note, however that b is the main parameter for such a correction scheme as it determines the linear response of the corrected output voltage V_{corr} while factor A-b determines the desired amplitude of the corrected output voltage V_{corr}. A particular example of this correction scheme is determined by Eq. 16b:

V_{corr}~β·tan h(Vₒᵤₜ/β) Eq. 16b.

with A=β, b=1/β and β are independent of the magnetic field vector H.

Similarly, output voltage Vₒᵤₜ of FIG. 9 can be linearized by a Sin h correction scheme leading to a corrected output voltage signal V_{corr} described by Eq. 17a:

V_{corr}=C·Vₒᵤₜ−A·sin h(b·Vₒᵤₜ) Eq. 17a,

where A, C and b are correction parameters that are independent of the external magnetic field vector H. Note, however that for such a correction scheme all three parameters A, C and b determine both the linear response of the corrected output voltage V_{corr} and the amplitude of the corrected output voltage V_{corr}. A particular example of this correction scheme is determined by Eq. 17b:

V_{corr}=2·Vₒᵤₜ−α·sin h(Vₒᵤₜ/α) Eq. 17b,

with A=α, b=1/α and α are independent of the magnetic field vector H.

In equations 17a and 17b, the second term corresponds to an additional voltage V_{add}, namely, V_{add}=A·sin h(b·Vₒᵤₜ) and V_{add}=α·sin h(Vₒᵤₜ/α), respectively.

In yet another embodiment, output voltage Vₒᵤₜ of FIG. 9 can be linearized by a Arc sin h correction scheme leading to a corrected output voltage signal V_{corr} described by Eq. 18a:

V_{corr}=A·arc sin h(b·Vₒᵤₜ) Eq. 18a,

where A and b are correction parameters that are independent of the external magnetic field vector H. Note, however that b is the main parameter for such a correction scheme as it determines the linear response of the corrected output voltage V_{corr} while factor A-b determines the desired amplitude of the corrected output voltage V_{corr}. A particular example of this correction scheme is determined by Eq. 18b:

V_{corr}=ω·arc sin h(Vₒᵤₜ/ω) Eq. 18b,

with A=ω, b=1/ω and ω are independent of the magnetic field vector H.

FIG. 9 shows the result of these correction schemes (Eq. 16b, 17b and 18b) in order to obtain a corrected output voltage V_{corr} with linearity error <0.4%. For this, the correction parameters α=1.07 V, β=1.23 V and ω=0.69 V were used. The corrected output voltage signal V_{corr} and its linearity error are compared with the output voltage signal Vₒᵤₜ the linearity error of output voltage signal Vₒᵤₜ. Note that linearity error is reduced from 4.6% up to a 0.11% (which is a ×40 reduction).

In another aspect, the corrected output voltage V_{corr} is determined by equation 19:

V_{corr}=C·Vₒᵤₜ−A·arc tan h(b·Vₒᵤₜ) Eq. 19,
where A, C and b are correction parameters that are independent of the external magnetic field vector H. Note, however that for such a correction scheme all three parameters A, C and b determines both the linear response of the corrected output voltage V_{corr} and the amplitude of the corrected output voltage V_{corr}. In another aspect, the corrected output voltage V_{corr} is determined by equation 20:

V_{corr}=C·Vₒᵤₜ−A·arc sin h(b·Vₒᵤₜ) Eq. 20,

where A, C and b are correction parameters that are independent of the external magnetic field vector H. Note, however that for such a correction scheme all three parameters A, C and b determine both the linear response of the corrected output voltage V_{corr} and the amplitude of the corrected output voltage V_{corr}.

In another aspect, the corrected output voltage V_{corr} is determined by equation 21:

V_{corr}=C·Vₒᵤₜ−A·cos h(b·Vₒᵤₜ) Eq. 21,

where A, C and b are correction parameters that are independent of the external magnetic field vector H. Note, however that for such a correction scheme all three parameters A, C and b determine both the linear response of the corrected output voltage V_{corr} and the amplitude of the corrected output voltage V_{corr}.

In yet another aspect, the corrected output voltage V_{corr} is determined by equation 22:

V_{corr}=D·Vₒᵤₜ−C·tan h(A·arc tan h(b·Vₒᵤₜ)) Eq. 22,

wherein A, C and D are correction parameters that are independent of the external magnetic field vector H.

The present disclosure further pertains to an integrated circuit (IC) comprises a processor configured to perform the steps of the method disclosed herein. In some aspects, the IC can comprise an application-specific integrated circuit (ASIC) die.

The present disclosure further pertains an intellectual property (IP) block configured to perform the method disclosed herein.

### Temperature Dependence

FIG. 10 shows the dependence on temperature of the output voltage signal Vₒᵤₜ (FIG. 10a) and linearity error (FIG. 10b) of a magnetic sensor as a function of temperature. The output voltage signal Vₒᵤₜ and linearity error were determined at −40 °C, 30 °C, 85 °C and 125 °C under external magnetic fields H up to 50 mT and using a bias voltage V_{dd} of 3.3V. Linearity errors between about 1.6% and 1.8% are obtained at all temperatures and a temperature coefficient of sensitivity (TCS) of about −420 ppm/°C. This implies a variation of Sensitivity of about 7.5% over the whole temperature range [−40 °C-125 °C].

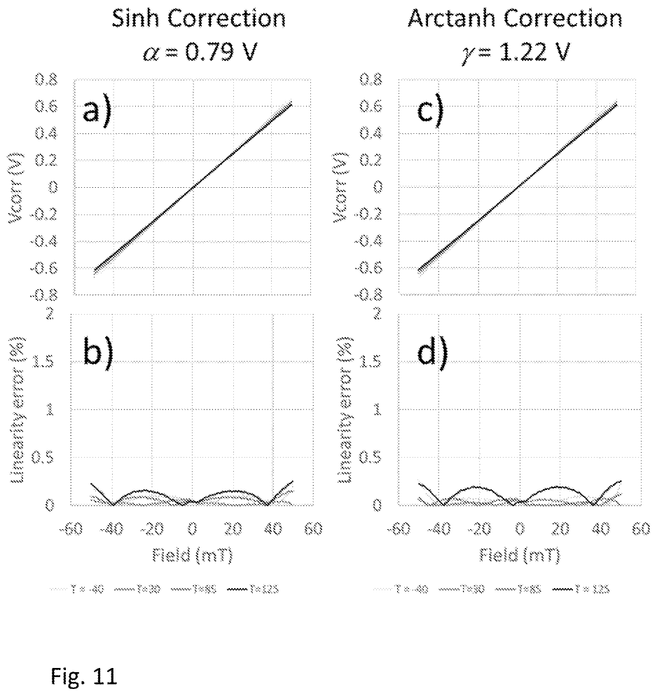

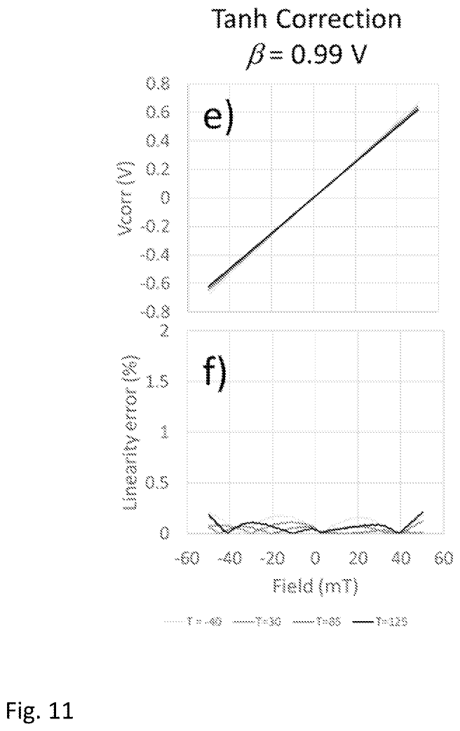

FIG. 11 reports the performance of correction schemes described by Eq. 8b, Eq. 9b and Eq. 10b for this magnetic sensor for the temperatures −40 °C, 30 °C, 85 °C and 125 °C and for optimal values of the correction parameters α=0.79 V, γ=1.22 V, and β=0.99 V when biased at 3.3 V. In particular, the corrected output voltage signal V_{corr} (FIGS. 11a, c and e) and linearity error (FIGS. 11b, d and f) are reported for the “Sin h” correction scheme (described by Eq. 9b) (FIGS. 11a, b), “Arc tan h” correction scheme (described by Eq. 8b) (FIGS. 11b, d), and “Tan h” correction scheme (described by Eq. 10b) (FIGS. 11e, f). A linearity error smaller than 0.3% is obtained for all temperatures.

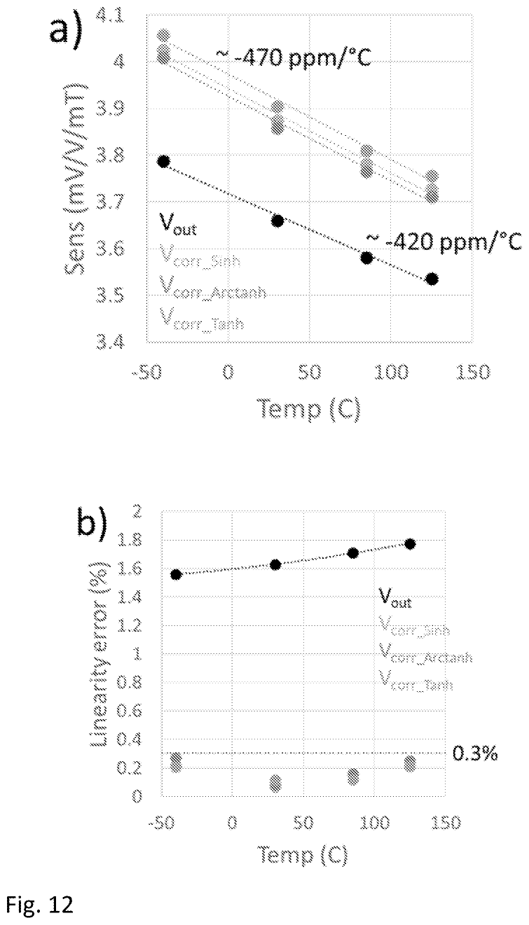

FIG. 12 reports the sensitivity (FIG. 12a) and the linearity error (FIG. 12b) of this magnetic sensor as a function of temperature for the correction parameters α=0.79V, γ=1.22 V, and β=0.99V of correction schemes described by Eq. 9b, Eq. 8b and Eq. 10b, respectively. After correction, the variation of Sensitivity with temperature, TCS is about −470 ppm/°C, which is very similar to the initial TCS of about −420 ppm/°C of the (uncorrected) output voltage signal Vₒᵤₜ.

The results shown show the potential of these correction schemes described by Eq. 8a, Eq. 9a and Eq. 10a and their robustness against temperature. However, other hyperbolic functions could be used for different dependence of the output voltage signal Vₒᵤₜ with respect to the external magnetic field H.

In an embodiment, correcting the output voltage signal Vₒᵤₜ can further comprise a correction of the TCS such as to further improve the linearity of the corrected output voltage signal V_{corr} of the magnetic sensor and obtain a magnetic sensor that has a stable sensitivity and linearity error with varying temperature.

In an embodiment, the corrected output voltage V_{corr} is determined by equation 23:

V_{corr}=A·Funct(b·Vₒᵤₜ) Eq. 23,

Wherein Vₒᵤₜ is the output voltage of the magnetic sensor, Funct(b·Vₒᵤₜ) is a hyperbolic function or an inverse hyperbolic function or a combination of a hyperbolic function or an inverse hyperbolic function of a signal proportional to Vₒᵤₜ(b·Vₒᵤₜ) and A and b are correction parameters independent of the magnetic field vector (H), wherein:

b=k·b₀/V_{dd} Eq. 24,

wherein b₀ is a correction coefficient, V_{dd} is a bias voltage applied to the sensor, and k is between 0.5 and 6.

In one aspect, in the case the corrected output voltage signal V_{corr} is described by any one of equations 9a or 18a, the correction coefficient b₀ can be defined by equation 25:

$${b}_{0} = \sqrt{\frac{6 \cdot {a}_{3}}{{a}_{1}^{3}}} , \qquad Eq . 25$$

where α₁ is a first order coefficient, α₃ is a third order coefficient of the magnetic sensor, and k is between 0.5 and 2.

In another aspect, in the case the corrected output voltage signal V_{corr} is described by any one of equations 8a, 12 or 16a the correction coefficient b₀ can be defined by equation 26:

$${b}_{0} = \sqrt{\frac{3 \cdot {a}_{3}}{{a}_{1}^{3}}} , \qquad Eq . 26$$

where α₁ is a first order coefficient, α₃ is a third order coefficient of the magnetic sensor, and k is between 0.5 and 6.

In yet another aspect, the corrected output voltage V_{corr} is determined by equation 27:

V_{corr}=C·Vₒᵤₜ−A·Funct(b·Vₒᵤₜ) Eq. 27,

Wherein Vₒᵤₜ is the output voltage of the magnetic sensor, Funct(b·Vₒᵤₜ) is a hyperbolic function or an inverse hyperbolic function or a combination of a hyperbolic function or an inverse hyperbolic function of a signal proportional to Vₒᵤₜ(b·Vₒᵤₜ) and A, b & C are correction parameters independent of the magnetic field vector (H), wherein:

C=p·A·b Eq. 28a

and:

b=k·b₀/V_{dd} Eq. 28b,

wherein b₀ is a correction coefficient, V_{dd} is a bias voltage applied to the sensor, and k is between 0.5 and 2 or between 0.5 and 6 and p>1.

In another aspect, in the case the corrected output voltage signal V_{corr} is described by any one of equations 10a or 19 the correction coefficient b₀ can be defined by equation 29:

$${b}_{0} = \sqrt{p - 1} \sqrt{\frac{3 \cdot {a}_{3}}{{a}_{1}^{3}}} , \qquad Eq . 29$$

where α₁ is a first order coefficient, α₃ is a third order coefficient of the magnetic sensor.

In another aspect, in the case the corrected output voltage signal V_{corr} is described by any one of equations 17a or 20 the correction coefficient b₀ can be defined by equation 30:

$${b}_{0} = \sqrt{p - 1} \sqrt{\frac{6 \cdot {a}_{3}}{{a}_{1}^{3}}} , \qquad Eq . 30$$

where α₁ is a first order coefficient, α₃ is a third order coefficient of the magnetic sensor.

Reference numbers and symbols

| | |
|---|---|
| 2 | magnetic sensor |
| 20 | magnetic sensing element |
| θ | orientation of the external magnetic field |
| γ, α and β | correction parameters |
| νₛ | dependence on magnetic field of a normalized output voltage |
| a₀ | sensor offset |
| a₁ | linear coefficient |
| a₂ⱼ₊₁ | high order component |
| a₃ | third order coefficient |
| H | external magnetic field |
| V_{add} | |
| V_{corr} | corrected output voltage signal |
| V_{dd} | bias voltage |
| Vₕₒ | high order component voltage |
| Vₒᵤₜ | output voltage signal |

1. A correction method for correcting an output voltage signal (Vₒᵤₜ) provided by a magnetic sensor, comprising:
providing a magnetic sensor, comprising at least a magnetic element, and generates the output voltage signal (Vₒᵤₜ) when inputted by a bias voltage (V_{dd}) and in the presence of an external magnetic field vector (H);
inputting the magnetic sensor by the bias voltage (V_{dd}) in the presence of the external magnetic field vector (H) such that the magnetic sensor generates the output voltage signal (Vₒᵤₜ); and
determining a corrected output voltage signal (V_{corr}) from the output voltage signal (Vₒᵤₜ) of the magnetic sensor, wherein the corrected output voltage signal (V_{corr}) has a linearity error smaller than the linearity error of the output voltage signal (Vₒᵤₜ) of the magnetic sensor;
characterized in that determining a corrected output voltage signal (V_{corr}) comprises:
applying a hyperbolic function or an inverse hyperbolic function or a combination of a hyperbolic function or an inverse hyperbolic function, to a signal proportional to the output voltage signal (Vₒᵤₜ); or
adding or subtracting an additional voltage signal (V_{add}) to the output voltage signal (Vₒᵤₜ), the additional voltage signal (V_{add}) being obtained by applying a hyperbolic function or an inverse hyperbolic function or a combination of both to a signal proportional to the output voltage signal (Vₒᵤₜ).

2. The correction method according to claim 1, wherein determining a corrected output voltage signal (V_{corr}) comprises applying a hyperbolic function or an inverse hyperbolic function or a combination of a hyperbolic function or an inverse hyperbolic function, to a signal proportional to the output voltage signal (Vₒᵤₜ).

3. The correction method according to claim 2, wherein the output voltage signal (Vₒᵤₜ) is approximated by:
Vₒᵤₜ=[α₀+α₁·H+Vₕₒ]·V_{dd};
wherein α₀ is an offset coefficient, α₁ is a first order coefficient and Vₕₒ is the high order component described by:
$${V}_{ho} = {\sum }_{j = 1}^{N} {a}_{2 j + 1} \cdot {H}^{2 j + 1} ;$$
wherein α₂ⱼ₊₁ are high order coefficients and the coefficients α₀, α₁ and α₂ⱼ₊₁ can be either positive, negative or zero.

4. The correction method according to claim 2, wherein the output voltage signal (Vₒᵤₜ) is approximated by:
Vₒᵤₜ=[α₀+α₁·θ+Vₕₒ]·V_{dd};
wherein θ is the orientation of the external magnetic field H with respect to a certain predefined axis in a coordinate system, V_{dd} is the bias voltage applied to the magnetic sensor, ai is an offset coefficient, α₁ is a first order coefficient and Vₕₒ is the high order component described by:
$${V}_{ho} = {\sum }_{j = 1}^{N} {a}_{2 j + 1} \cdot {θ}^{2 j + 1} ;$$
wherein α₂ⱼ₊₁ are high order coefficients and the coefficients α₀, α₁ and α₂ⱼ₊₁ can be either positive, negative or zero.

5. The correction method according to claim 2, wherein the corrected output voltage (V_{corr}) is determined by:
V_{corr}=A·sin h(b·Vₒᵤₜ);
wherein A and b are correction parameters independent of the magnetic field vector (H).

6. The correction method according to claim 2, wherein the corrected output voltage (V_{corr}) is determined by:
V_{corr}=A·cos h(b·Vₒᵤₜ);
wherein A and b are correction parameters independent of the magnetic field vector (H).

7. The correction method according to claim 2, wherein the corrected output voltage (V_{corr}) is determined by:
V_{corr}=A·tan h(b·Vₒᵤₜ);
wherein A and b are correction parameters independent of the magnetic field vector (H).

8. The correction method according to claim 2, wherein the corrected output voltage (V_{corr}) is determined by:
V_{corr}=A·arc tan h(b·Vₒᵤₜ);
wherein A and b are correction parameters independent of the magnetic field vector (H).

9. The correction method according to claim 2, wherein the corrected output voltage (V_{corr}) is determined by:
V_{corr}=A·arc sin h(b·Vₒᵤₜ);
wherein A and b are correction parameters independent of the magnetic field vector (H).

10. The correction method according to claim 2, wherein the corrected output voltage (V_{corr}) is determined by:
V_{corr}=C·tan h(A·arc tan h(b·Vₒᵤₜ));
wherein A, C and b are correction parameters independent of the magnetic field vector (H).

11. The correction method according to claim 1, wherein determining a corrected output voltage signal (V_{corr}) comprises adding or subtracting an additional voltage signal (V_{add}) to the output voltage signal (Vₒᵤₜ), the additional voltage signal (V_{add}) being obtained by applying a hyperbolic function or an inverse hyperbolic function or a combination of both to a signal proportional to the output voltage signal (Vₒᵤₜ).

12. The correction method according to claim 11, wherein the output voltage signal (Vₒᵤₜ) is approximated by:
Vₒᵤₜ=[α₀+α₁ H+Vₕₒ]·V_{dd};
wherein α₀ is an offset coefficient, α₁ is a first order coefficient and Vₕₒ is the high order component described by:
$${V}_{ho} = {\sum }_{j = 1}^{N} {a}_{2 j + 1} \cdot {H}^{2 j + 1} ;$$
wherein α₂ⱼ₊₁ are high order coefficients and the coefficients α₀, α₁ and α₂ⱼ₊₁ can be either positive, negative or zero.

13. The correction method according to claim 11, wherein the output voltage signal (Vₒᵤₜ) is approximated by:
Vₒᵤₜ=[α₀+α₁·θ+Vₕₒ]·V_{dd};
wherein θ is the orientation of the external magnetic field H with respect to a certain predefined axis in a coordinate system, V_{dd} is the bias voltage applied to the magnetic sensor, a₀ is an offset coefficient, α₁ is a first order coefficient and Vₕₒ is the high order component described by:
$${V}_{ho} = {\sum }_{j = 1}^{N} {a}_{2 j + 1} \cdot {θ}^{2 j + 1} ;$$
wherein α₂ⱼ₊₁ are high order coefficients and the coefficients α₀, α₁ and α₂ⱼ₊₁ can be either positive, negative or zero.

14. The correction method according to claim 11, wherein the corrected output voltage (V_{corr}) is determined by:
V_{corr}=C·Vₒᵤₜ−A·sin h(b·Vₒᵤₜ);
wherein A, C and b are correction parameters independent of the magnetic field vector (H).

15. The correction method according to claim 10, wherein the corrected output voltage (V_{corr}) is determined by:
V_{corr}=C·Vₒᵤₜ−A·cos h(b·Vₒᵤₜ);
wherein A, C and b are correction parameters independent of the magnetic field vector (H).

16. The correction method according to claim 11, wherein the corrected output voltage (V_{corr}) is determined by:
V_{corr}=C·Vₒᵤₜ−A·tan h(b·Vₒᵤₜ);
wherein A, C and b are correction parameters independent of the magnetic field vector (H).

17. The correction method according to claim 11, wherein the corrected output voltage (V_{corr}) is determined by:
V_{corr}=C·Vₒᵤₜ−A·arc tan h(b·Vₒᵤₜ);
wherein A, C and b are correction parameters independent of the magnetic field vector (H).

18. The correction method according to claim 11, wherein the corrected output voltage (V_{corr}) is determined by:
V_{corr}=C·Vₒᵤₜ−A·arc sin h(b·Vₒᵤₜ);
wherein A, C are and b are correction parameters independent of the magnetic field vector (H).

19. The correction method according to claim 10, wherein the corrected output voltage (V_{corr}) is determined by:
V_{corr}=D·Vₒᵤₜ−C·tan h(A·arc tan h(b·Vₒᵤₜ));
wherein A, C and D and b are correction parameters independent of the magnetic field vector (H).

20. The correction method according to claim 3, wherein the corrected output voltage (V_{corr}) is determined by:
V_{corr}=A·Funct(b·Vₒᵤₜ);
wherein Funct(b·Vₒᵤₜ) is a hyperbolic function or an inverse hyperbolic function or a combination of a hyperbolic function or an inverse hyperbolic function of a signal proportional to the output voltage signal (Vₒᵤₜ) of the magnetic sensor, A and b are correction parameters independent of the magnetic field vector (H), and wherein
b=k·b₀/V_{dd}
wherein b₀ is a correction coefficient, V_{dd} is a bias voltage applied to the magnetic sensor, and k is between 0.5 and 2.

21. The correction method according to claim 5, wherein
$${b}_{0} = \sqrt{\frac{{a}_{3}}{{a}_{1}^{3}}} ,$$
wherein α₁ is a first order coefficient and α₃ is a third order coefficient of the output voltage response (Vₒᵤₜ) of the magnetic sensor.

22. The correction method according to claim 12, wherein the corrected output voltage (V_{corr}) is determined by:
V_{corr}=C·Vₒᵤₜ−A·Funct(b·Vₒᵤₜ);
wherein Vₒᵤₜ is the output voltage of the magnetic sensor, Funct(b·Vₒᵤₜ) is a hyperbolic function or an inverse hyperbolic function or a combination of a hyperbolic function or an inverse hyperbolic function of a signal proportional to the output voltage signal (Vₒᵤₜ) of the magnetic sensor, wherein A, b and C are correction parameters independent of the magnetic field vector (H), and wherein
C=p·A·b
and
b=k·b₀/V_{dd}
wherein b₀ is a correction coefficient, V_{dd} is a bias voltage applied to the magnetic sensor, and k is between 0.5 and 2, and p>1.

23. The correction method according to claim 14, wherein
$${b}_{0} = \sqrt{p - 1} \sqrt{\frac{{a}_{3}}{{a}_{1}^{3}}} ,$$
wherein α₁ is a first order coefficient and α₃ is a third order coefficient of the output voltage response (Vₒᵤₜ) of the magnetic sensor.

24. The correction method according to claim 1, wherein the magnetic sensor is a MTJ-based magnetic sensor comprising at least a magnetoresistive element.

25. An integrated circuit (IC) comprising a processor configured to perform the steps of claim 1.

26. An intellectual property (IP) block configured to perform the method of claim 1.
